(19) United States
(12) Patent Application Publication
(10) Pub. No.: US 2025/0248039 A1
(43) Pub. Date: Jul. 31, 2025

(54) SEMICONDUCTOR DEVICE INCLUDING RESONANT TUNNELING LAYER

(71) Applicant: SK hynix Inc., Gyeonggi-do (KR)

(72) Inventor: Hwan Young KIM, Gyeonggi-do (KR)

(21) Appl. No.: 18/732,621

(22) Filed: Jun. 4, 2024

(30) Foreign Application Priority Data
Jan. 25, 2024 (KR) 10-2024-0011344

(51) Int. Cl. H10B 43/30; H01L 29/792; H10B 43/27

(52) U.S. Cl. CPC H10B 43/30; H10B 43/27; H10D 30/69

(57) ABSTRACT

A semiconductor device may include an electrode over a channel pattern. An information storage pattern may be disposed between the channel pattern and the electrode. The information storage pattern may include a tunnel layer adjacent to the channel pattern; a blocking layer adjacent to the electrode; a charge trap layer between the tunnel layer and the blocking layer; a first resonant tunneling layer disposed between the tunnel layer and the charge trap layer, and including a material having a lower energy barrier than the tunnel layer; and a second resonant tunneling layer disposed between the charge trap layer and the blocking layer, and including a material having a lower energy barrier than the charge trap layer.

### CROSS-REFERENCE TO RELATED APPLICATION

The present application claims priority under 35 U.S.C. § 119(a) to Korean Patent Application No. 10-2024-0011344 filed on Jan. 25, 2024, which is incorporated herein by reference in its entirety.

### BACKGROUND

### 1. Technical Field

Various embodiments of the present disclosure generally relate to a semiconductor device including a resonant tunneling layer and a method of forming the same.

### 2. Related Art

Various technologies are being attempted for high integration of a nonvolatile memory device. The nonvolatile memory device is a memory in which stored data is preserved even when power supply is interrupted, and includes a PROM (programmable ROM) and a flash memory. Increasing the operation speed and minimizing the power consumption of the nonvolatile memory device face various technical limitations.

### SUMMARY

Various embodiments of the present disclosure are directed to providing a semiconductor device which is advantageous for improving operation speed and reducing power consumption, and a method of forming the same.

In an embodiment of the present disclosure, a semiconductor device may include an electrode over a channel pattern. An information storage pattern may be disposed between the channel pattern and the electrode. The information storage pattern may include a tunnel layer adjacent to the channel pattern; a blocking layer adjacent to the electrode; a charge trap layer between the tunnel layer and the blocking layer; a first resonant tunneling layer disposed between the tunnel layer and the charge trap layer, and including a material having a lower energy barrier than the tunnel layer; and a second resonant tunneling layer disposed between the charge trap layer and the blocking layer, and including a material having a lower energy barrier than the charge trap layer.

In an embodiment of the present disclosure, a semiconductor device may include an electrode over a channel pattern. An information storage pattern may be disposed between the channel pattern and the electrode. The information storage pattern may include a tunnel layer adjacent to the channel pattern; a blocking layer adjacent to the electrode; a charge trap layer between the tunnel layer and the blocking layer; and at least one resonant tunneling layer disposed between the tunnel layer and the blocking layer, and including a material having a lower energy barrier than the tunnel layer and the blocking layer.

In an embodiment of the present disclosure, a semiconductor device may include a stack structure including a plurality of molding layers and a plurality of horizontal electrodes which are alternately stacked. A source line may be disposed on the stack structure. A channel structure passing through the stack structure and extending into the source line may be provided. The channel structure may include a channel pattern contacting the source line; and an information storage pattern between the channel pattern and the stack structure. The information storage pattern may include a tunnel layer adjacent to the channel pattern; a blocking layer adjacent to the stack structure; a charge trap layer between the tunnel layer and the blocking layer; and at least one resonant tunneling layer disposed between the tunnel layer and the blocking layer, and including a material having a lower energy barrier than the tunnel layer and the blocking layer.

According to the embodiments of the present disclosure, it is possible to implement a semiconductor device which is advantageous for high speed operation, is capable of high speed switching and achieves low power consumption.

### BRIEF DESCRIPTION OF THE DRAWINGS

FIGS. 1 to 4 are cross-sectional views for describing semiconductor devices based on embodiments of the present disclosure.

FIG. 5 is a plan view for describing the semiconductor device according to an embodiment of the present disclosure.

FIG. 6 is a cross-sectional view for describing a semiconductor device based on an embodiment of the present disclosure.

FIGS. 7 to 17 are cross-sectional views for explaining methods of forming semiconductor devices based on embodiments of the present disclosure.

### DETAILED DESCRIPTION

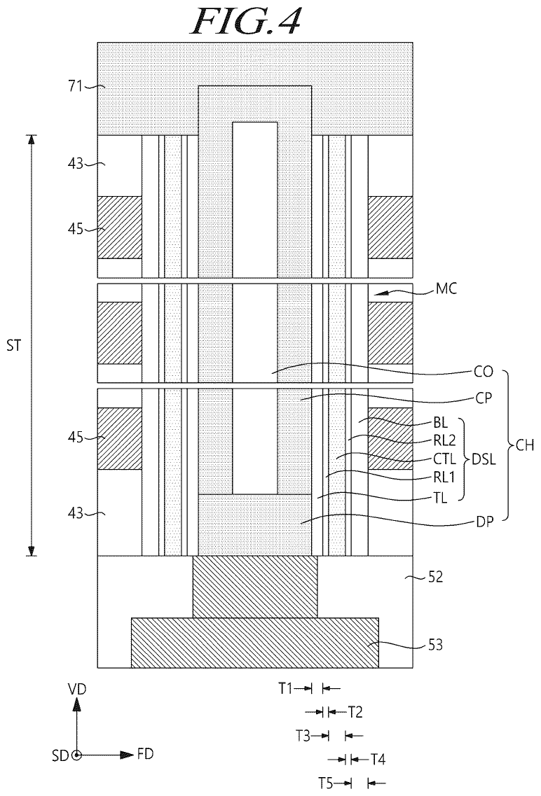

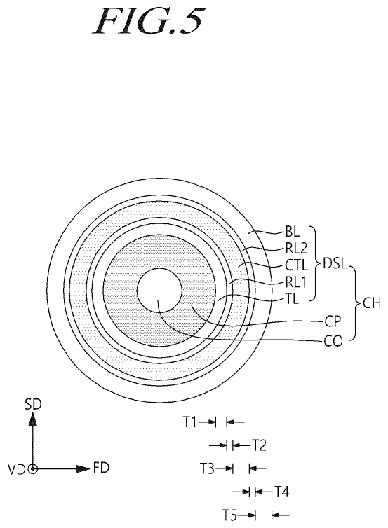

FIGS. 1 to 4 are cross-sectional views for describing semiconductor devices based on embodiments of the present disclosure, and FIG. 5 is a plan view for describing the semiconductor device according to an embodiment of the present disclosure. In an embodiment, FIG. 5 may correspond to a part (e.g., a channel structure CH) of FIG. 4. FIG. 6 is a cross-sectional view for describing a semiconductor device based on an embodiment of the present disclosure. In an embodiment, the semiconductor device based on the embodiments of the present disclosure may include a nonvolatile memory device such as a flash memory.

Referring to FIG. 1, the semiconductor device according to an embodiment of the present disclosure may include a first substrate 21, a source region 23, a drain region 25, a channel pattern CP, an information storage pattern DSL, and a top electrode 29. The information storage pattern DSL may include a tunnel layer TL, a first resonant tunneling layer RL1, a charge trap layer CTL, a second resonant tunneling layer RL2, and a blocking layer BL.

A first direction FD, a second direction SD and a third direction VD may be defined. The second direction SD may intersect the first direction FD. The third direction VD may intersect the first direction FD and the second direction SD. In an embodiment, the first direction FD and the second direction SD may be parallel to the upper (i.e., the top) surface and the lower (i.e., the bottom) surface of the first substrate 21. The third direction VD may be perpendicular to the upper surface and the lower surface of the first substrate 21. The second direction SD may be perpendicular to the first direction FD. The third direction VD may be perpendicular to the first direction FD and the second direction SD.

The channel pattern CP may be disposed between the source and the drain regions 23 and 25 in the first substrate 21. In an embodiment, the channel pattern CP may include a semiconductor layer having P-type impurities. The channel pattern CP may include a monocrystalline silicon layer, a polysilicon layer or a combination thereof, having P-type impurities. Each of the source and the drain regions 23 and 25 may include a semiconductor layer having N-type impurities. Each of the source and the drain regions 23 and 25 may include a monocrystalline silicon layer, a polysilicon layer or a combination thereof, having N-type impurities.

The information storage pattern DSL may be disposed on the channel pattern CP in the third direction VD. The information storage pattern DSL may fully overlap with the channel pattern CP in the third direction VD. The top electrode 29 may be disposed on the information storage pattern DSL in the third direction VD. The information storage pattern DSL may fully overlap with the top electrode 29 and the channel pattern CP and may be disposed between the top electrode 29 and the channel pattern CP. In an embodiment, the channel pattern CP, the information storage pattern DSL and the top electrode 29 may be configured to form a nonvolatile memory cell. The top electrode 29 may be connected to a word line or the top electrode 29 may correspond to a portion of a word line.

The tunnel layer TL, the first resonant tunneling layer RL1, the charge trap layer CTL, the second resonant tunneling layer RL2 and the blocking layer BL may be sequentially stacked in the third direction VD. The tunnel layer TL may have a first thickness T1. The first resonant tunneling layer RL1 may have a second thickness T2. The charge trap layer CTL may have a third thickness T3. The second resonant tunneling layer RL2 may have a fourth thickness T4. The blocking layer BL may have a fifth thickness T5. The equivalent oxide thickness (EOT) of the blocking layer BL may be thicker than the equivalent oxide thickness (EOT) of the tunnel layer TL. The fifth thickness T5 of the blocking layer BL may be thicker than the first thickness T1 of the tunnel layer TL.

The tunnel layer TL may be disposed on the channel pattern CP. The tunnel layer TL may contact the channel pattern CP. The tunnel layer TL may be disposed between the channel pattern CP and the charge trap layer CTL. The first resonant tunneling layer RL1 may be disposed on the tunnel layer TL. The first resonant tunneling layer RL1 may be disposed between the tunnel layer TL and the charge trap layer CTL. The first resonant tunneling layer RL1 may contact the tunnel layer TL and the charge trap layer CTL.

The charge trap layer CTL may be disposed on the first resonant tunneling layer RL1. The charge trap layer CTL may be disposed between the first resonant tunneling layer RL1 and the second resonant tunneling layer RL2. The charge trap layer CTL may contact the first resonant tunneling layer RL1 and the second resonant tunneling layer RL2. The charge trap layer CTL may be disposed between the tunnel layer TL and the blocking layer BL. The second resonant tunneling layer RL2 may be disposed on the charge trap layer CTL. The second resonant tunneling layer RL2 may be disposed between the charge trap layer CTL and the blocking layer BL. The second resonant tunneling layer RL2 may contact the charge trap layer CTL and the blocking layer BL.

The blocking layer BL may be disposed on the second resonant tunneling layer RL2. The blocking layer BL may contact the second resonant tunneling layer RL2. The blocking layer BL may be disposed between the second resonant tunneling layer RL2 and the top electrode 29. The blocking layer BL may be disposed between the charge trap layer CTL and the top electrode 29.

The first resonant tunneling layer RL1 may include a material different from that of the tunnel layer TL. The first resonant tunneling layer RL1 may include a material having a lower energy barrier than the tunnel layer TL. The tunnel layer TL may include silicon oxide, silicon nitride, aluminum oxide (Al2O3), magnesium oxide (MgO) or zirconium oxide (ZrO2). The first resonant tunneling layer RL1 may include tantalum pentoxide (Ta2O5), gallium oxide (Ga2O3), gadolinium oxide (Gd2O3), lanthanum oxide (La2O3), hafnium oxide (HfO2), gallium nitride (GaN), or a combination thereof. In an embodiment, the first resonant tunneling layer RL1 may include a tantalum pentoxide (Ta2O5) layer. The first resonant tunneling layer RL1 may include a material having a lower energy barrier than the charge trap layer CTL. The first resonant tunneling layer RL1 may include a material having a lower energy barrier than the blocking layer BL.

The second thickness T2 of the first resonant tunneling layer RL1 may be smaller than the first thickness T1 of the tunnel layer TL. The tunnel layer TL may, for example, have a thickness of 1 nm to 7 nm. The first resonant tunneling layer RL1 may, for example, have a thickness of 0.5 nm to 3 nm.

The charge trap layer CTL may include a material which is different from those of the first resonant tunneling layer RL1, the second resonant tunneling layer RL2 and the blocking layer BL. The charge trap layer CTL may include a material having a higher energy barrier than the first resonant tunneling layer RL1. In an embodiment, the charge trap layer CTL may include silicon nitride. The charge trap layer CTL may include a material having a lower energy barrier than the tunnel layer TL and the blocking layer BL.

The second resonant tunneling layer RL2 may include a material which is different from those of the charge trap layer CTL and the blocking layer BL. The second resonant tunneling layer RL2 may include a material having a lower energy barrier than the charge trap layer CTL. The second resonant tunneling layer RL2 may include tantalum pentoxide (Ta2O5), gallium oxide (Ga2O3), gadolinium oxide (Gd2O3), lanthanum oxide (La2O3), hafnium oxide (HfO2), gallium nitride (GaN), or a combination thereof. In an embodiment, the second resonant tunneling layer RL2 may include a tantalum pentoxide (Ta2O5) layer. The second resonant tunneling layer RL2 may include a material having a lower energy barrier than the blocking layer BL. The second resonant tunneling layer RL2 may include a material having a lower energy barrier than the tunnel layer TL.

The fourth thickness T4 of the second resonant tunneling layer RL2 may be smaller than the first thickness T1 of the tunnel layer TL. The second resonant tunneling layer RL2 may, for example, have a thickness of 0.5 nm to 3 nm.

The blocking layer BL may include a material which is different from those of the second resonant tunneling layer RL2 and the charge trap layer CTL. The blocking layer BL may include a material having a higher energy barrier than the second resonant tunneling layer RL2 and the charge trap layer CTL. In an embodiment, the blocking layer BL may include aluminum oxide (Al2O3).

In an embodiment, the program operation of the semiconductor device according to an embodiment of the present disclosure may be performed using a resonant tunneling injection (RTI) method. While the program operation of the semiconductor device is performed, electrons passing through the tunnel layer TL from the channel pattern CP may be injected into the charge trap layer CTL by passing through the first resonant tunneling layer RL1. Some of the electrons injected into the charge trap layer CTL may pass through the charge trap layer CTL and pass through the second resonant tunneling layer RL2 to be reflected at the blocking layer BL. The electrons reflected at the blocking layer BL may be injected into the charge trap layer CTL by passing through the second resonant tunneling layer RL2. According to the embodiment of the disclosed technology, it is possible to implement a semiconductor device which is advantageous for high speed operation, is capable of high speed switching and achieves low power consumption.

Since it is possible to inject a relatively large number of electrons into the charge trap layer CTL with a relatively low voltage by the resonant tunneling injection (RTI) method, the on/off characteristics of a nonvolatile memory device may be improved. Also, the endurance characteristics of the nonvolatile memory device may be improved. In the nonvolatile memory device, a relatively large number of level states may be implemented.

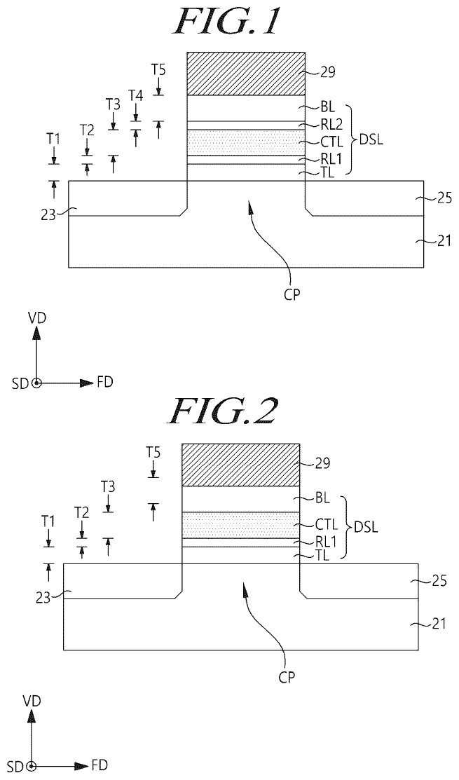

Referring to FIG. 2, the information storage pattern DSL may include a tunnel layer TL, a first resonant tunneling layer RL1, a charge trap layer CTL and a blocking layer BL. The charge trap layer CTL may be disposed between the first resonant tunneling layer RL1 and the blocking layer BL. The charge trap layer CTL may contact the first resonant tunneling layer RL1 and the blocking layer BL.

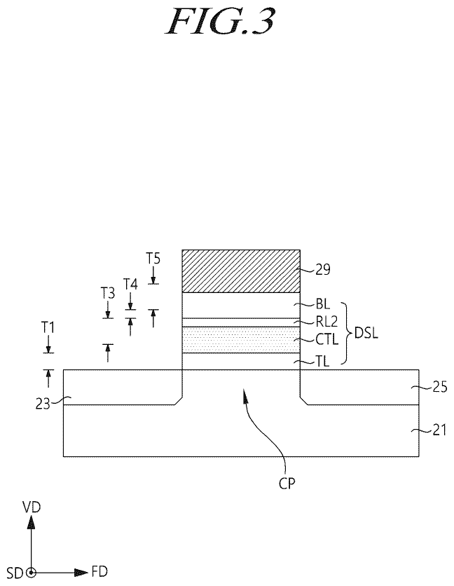

Referring to FIG. 3, the information storage pattern DSL may include a tunnel layer TL, a charge trap layer CTL, a second resonant tunneling layer RL2 and a blocking layer BL. The charge trap layer CTL may be disposed between the tunnel layer TL and the second resonant tunneling layer RL2. The charge trap layer CTL may contact the tunnel layer TL and the second resonant tunneling layer RL2. The second resonant tunneling layer RL2 may be disposed between the charge trap layer CTL and the blocking layer BL.

Referring to FIG. 4, the semiconductor device according to an embodiment of the present disclosure may include a stack structure ST, a channel structure CH, an interlayer insulating layer 52, a bit line 53, and a source line 71 covering the stack structure ST. FIG. 4 may correspond to a cross-sectional view taken on a plane formed in the first direction FD and the third direction VD.

The stack structure ST may include a plurality of molding layers 43 and a plurality of horizontal electrodes 45 which are alternately stacked in the third direction VD. The uppermost layer and the lowermost layer of the stack structure ST may be molding layers 43. The source line 71 may be disposed on the channel structure CH in the third direction VD. The channel structure CH may include a core layer CO, a channel pattern CP, an information storage pattern DSL and a drain pad DP. The information storage pattern DSL may include a tunnel layer TL, a first resonant tunneling layer RL1, a charge trap layer CTL, a second resonant tunneling layer RL2 and a blocking layer BL. The channel structure CH may extend into the source line 71 by passing through the stack structure ST in the third direction VD.

Specifically, the core layer CO may extend into the source line 71 by passing through the stack structure ST in the third direction VD. The channel pattern CP may surround the side surface and the upper (i.e., top) surface of the core layer CO. Hence, the channel pattern CP may also extend into the source line 71. The channel pattern CP may directly contact the source line 71.

The information storage pattern DSL may surround the side surface of the channel pattern CP. The channel pattern CP may be disposed between the information storage pattern DSL and the core layer CO. The information storage pattern DSL may be disposed between the channel pattern CP and the stack structure ST. The information storage pattern DSL may include a configuration similar to that described above with reference to FIGS. 1 to 3.

In an embodiment, the tunnel layer TL may be disposed on the side surface of the channel pattern CP in the first direction FD. The tunnel layer TL may contact the channel pattern CP. The tunnel layer TL may be disposed between the channel pattern CP and the charge trap layer CTL. The first resonant tunneling layer RL1 may be disposed on the side surface of the tunnel layer TL in the first direction FD. The first resonant tunneling layer RL1 may be disposed between the tunnel layer TL and the charge trap layer CTL.

The charge trap layer CTL may be disposed on the side surface of the first resonant tunneling layer RL1 in the first direction FD. The charge trap layer CTL may be disposed between the first resonant tunneling layer RL1 and the second resonant tunneling layer RL2. The charge trap layer CTL may be disposed between the tunnel layer TL and the blocking layer BL. The second resonant tunneling layer RL2 may be disposed on the side surface of the charge trap layer CTL in the first direction FD. The second resonant tunneling layer RL2 may be disposed between the charge trap layer CTL and the blocking layer BL.

The blocking layer BL may be disposed on the side surface of the second resonant tunneling layer RL2 in the first direction FD. The blocking layer BL may be disposed between the second resonant tunneling layer RL2 and the stack structure ST. The blocking layer BL may contact the stack structure ST. The blocking layer BL may extend between the second resonant tunneling layer RL2 and the plurality of horizontal electrodes 45 and between the second resonant tunneling layer RL2 and the plurality of molding layers 43. The blocking layer BL may contact the second resonant tunneling layer RL2 and the plurality of horizontal electrodes 45. The blocking layer BL may be disposed between the charge trap layer CTL and the stack structure ST.

The tunnel layer TL may have a first thickness T1 in the first direction FD. The first resonant tunneling layer RL1 may have a second thickness T2 in the first direction FD. The charge trap layer CTL may have a third thickness T3 in the first direction FD. The second resonant tunneling layer RL2 may have a fourth thickness T4 in the first direction FD. The blocking layer BL may have a fifth thickness T5 in the first direction FD. The equivalent oxide thickness (EOT) of the blocking layer BL may be thicker than the equivalent oxide thickness (EOT) of the tunnel layer TL. The fifth thickness T5 of the blocking layer BL may be thicker than the first thickness T1 of the tunnel layer TL.

The drain pad DP may be disposed on the lower (i.e., bottom) surfaces of the channel pattern CP and the core layer CO. The drain pad DP may directly contact the channel pattern CP and the core layer CO. The interlayer insulating layer 52 may be disposed on the lower (i.e., bottom) surfaces of the stack structure ST and the channel structure CH. The bit line 53 may be disposed in the interlayer insulating layer 52. The bit line 53 may be connected to the drain pad DP.

In an embodiment, the source line 71 may correspond to a common source line. The plurality of horizontal electrodes 45 may include a plurality of word lines, a plurality of select lines and at least one gate induced drain leakage (GIDL) control line. Memory cells MC may be formed at the intersections of the channel structure CH and the plurality of word lines. At least one adjacent to the source line 71 among the plurality of horizontal electrodes 45 may correspond to a source select line. At least one adjacent to the drain pad DP among the plurality of first horizontal electrodes 45 may correspond to a drain select line. One adjacent to the source line 71 among the plurality of horizontal electrodes 45 and/or one adjacent to the drain pad DP among the plurality of horizontal electrodes 45 may correspond to a GIDL control line. The plurality of word lines may be disposed between the at least one drain select line and the at least one source select line among the plurality of horizontal electrodes 45.

FIG. 5 may correspond to a plan view taken when viewing a part (e.g., the channel structure CH) of FIG. 4 on a plane formed in the first direction FD and the second direction SD according to an embodiment of the present disclosure.

Referring to FIG. 5, the channel pattern CP may surround the side surface of the core layer CO. The information storage pattern DSL may surround the side surface of the channel pattern CP. The channel pattern CP may be disposed between the core layer CO and the information storage pattern DSL. The information storage pattern DSL may include a configuration similar to that described above with reference to FIGS. 1 to 3. In an embodiment, the information storage pattern DSL may include the tunnel layer TL which surrounds the outside of the channel pattern CP, the first resonant tunneling layer RL1 which surrounds the outside of the tunnel layer TL, the charge trap layer CTL which surrounds the outside of the first resonant tunneling layer RL1, the second resonant tunneling layer RL2 which surrounds the outside of the charge trap layer CTL, and the blocking layer BL which surrounds the outside of the second resonant tunneling layer RL2.

Referring to FIG. 6, the semiconductor device according to an embodiment of the present disclosure may include a second substrate 31, a circuit structure CS, a first insulating bonding layer 38, a plurality of first bonding pads 39, a stack structure ST, a buried insulating layer 47, a plurality of channel structures CH, a plurality of contact plugs 49, an interlayer insulating layer 52, a plurality of intermediate interconnections 53 and 54, a second insulating bonding layer 62, a plurality of second bonding pads 63, a source line 71, and an upper insulating layer 98.

The circuit structure CS may include a page buffer PB, a decoder DE and a circuit insulating layer 34. The stack structure ST may include a plurality of molding layers 43 and a plurality of horizontal electrodes 45 which are alternately stacked in the third direction VD. Similarly to the illustration of FIG. 4, each of the plurality of channel structures CH may include a core layer CO, a channel pattern CP, an information storage pattern DSL and a drain pad DP. In an embodiment, the information storage pattern DSL may include a tunnel layer TL, a first resonant tunneling layer RL1, a charge trap layer CTL, a second resonant tunneling layer RL2 and a blocking layer BL. The plurality of intermediate interconnections 53 and 54 may include a plurality of bit lines 53 and a plurality of word connecting interconnections 54.

One selected from among the plurality of channel structures CH may be connected to the page buffer PB via a corresponding one among the plurality of bit lines 53, a corresponding one among the plurality of second bonding pads 63 and a corresponding one among the plurality of first bonding pads 39. One selected from among the plurality of horizontal electrodes 45 may be connected to the decoder DE via a corresponding one among the plurality of contact plugs 49, a corresponding one among the plurality of word connecting interconnections 54, a corresponding one among the plurality of second bonding pads 63 and a corresponding one among the plurality of first bonding pads 39.

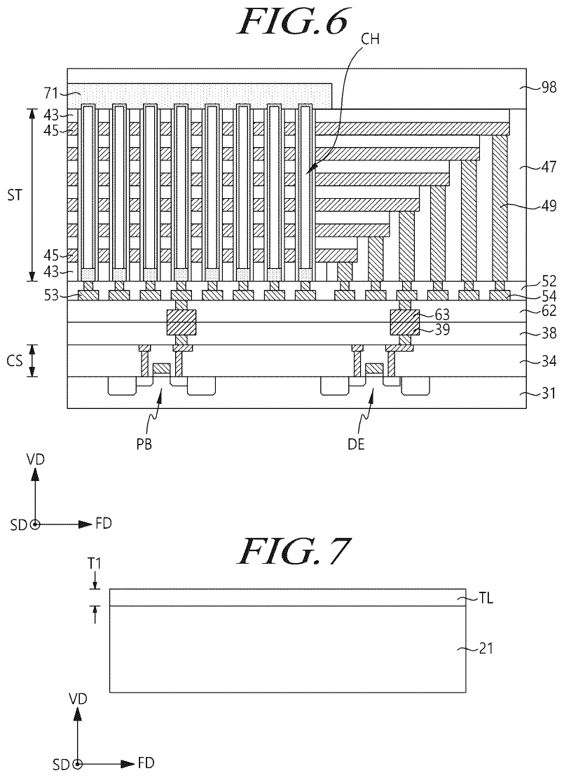

FIGS. 7 to 12 are cross-sectional views for describing a method of forming a semiconductor device based on an embodiment of the present disclosure.

Referring to FIG. 7, a tunnel layer TL having a first thickness T1 may be formed on a first substrate 21.

The first substrate 21 may include a semiconductor substrate such as a silicon wafer or an SOI (silicon on insulator) wafer. The first substrate 21 may include a III-V group semiconductor substrate, for example, a compound semiconductor substrate such as GaAs. The first substrate 21 may include monocrystalline silicon, polysilicon, amorphous silicon, monocrystalline silicon germanium, polycrystalline silicon germanium, carbon-doped silicon, or a combination thereof. In an embodiment, the first substrate 21 may include a monocrystalline silicon wafer having P-type impurities.

The tunnel layer TL may include silicon oxide, silicon nitride, aluminum oxide (Al2O3), magnesium oxide (MgO) or zirconium oxide (ZrO2). Forming the tunnel layer TL may include a chemical vapor deposition (CVD) method, an atomic layer deposition (ALD) method, a cyclic deposition method, a sputtering method, a physical vapor deposition (PVD) method, or a combination thereof. The tunnel layer TL may be formed to cover the first substrate 21 with a uniform thickness. The tunnel layer TL may, for example, have a thickness of 1 nm to 7 nm.

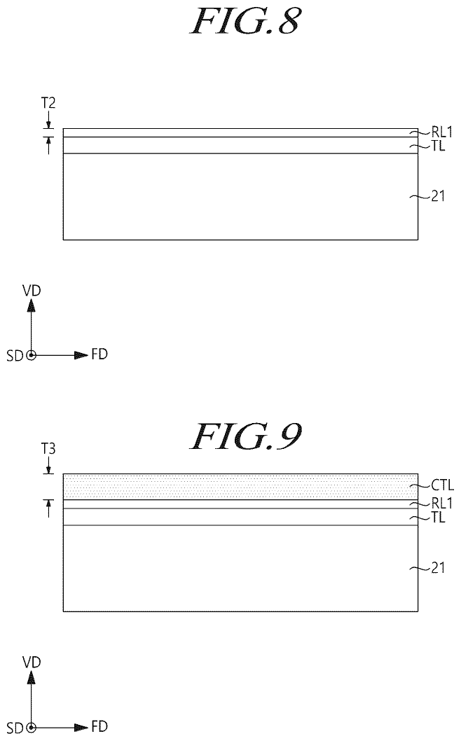

Referring to FIG. 8, a first resonant tunneling layer RL1 having a second thickness T2 may be formed on the tunnel layer TL to cover the tunnel layer TL. The first resonant tunneling layer RL1 may include a material having a lower energy barrier than the tunnel layer TL. The first resonant tunneling layer RL1 may include tantalum pentoxide (Ta2O5), gallium oxide (Ga2O3), gadolinium oxide (Gd2O3), lanthanum oxide (La2O3), hafnium oxide (HfO2), gallium nitride (GaN), or a combination thereof. In an embodiment, the first resonant tunneling layer RL1 may include a tantalum pentoxide (Ta2O5) layer.

Forming the first resonant tunneling layer RL1 may include a chemical vapor deposition (CVD) method, an atomic layer deposition (ALD) method, a cyclic deposition method, a sputtering method, a physical vapor deposition (PVD) method, or a combination thereof. The second thickness T2 of the first resonant tunneling layer RL1 may be smaller than the first thickness T1 of the tunnel layer TL. The first resonant tunneling layer RL1 may, for example, have a thickness of 0.5 nm to 3 nm.

Referring to FIG. 9, a charge trap layer CTL having a third thickness T3 may be formed on the first resonant tunneling layer RL1. The charge trap layer CTL may include a material having a higher energy barrier than the first resonant tunneling layer RL1. In an embodiment, the charge trap layer CTL may include a silicon nitride layer. The charge trap layer CTL may include a material having a lower energy barrier than the tunnel layer TL. Forming the charge trap layer CTL may include a chemical vapor deposition (CVD) method, an atomic layer deposition (ALD) method, a cyclic deposition method, a sputtering method, a physical vapor deposition (PVD) method, or a combination thereof.

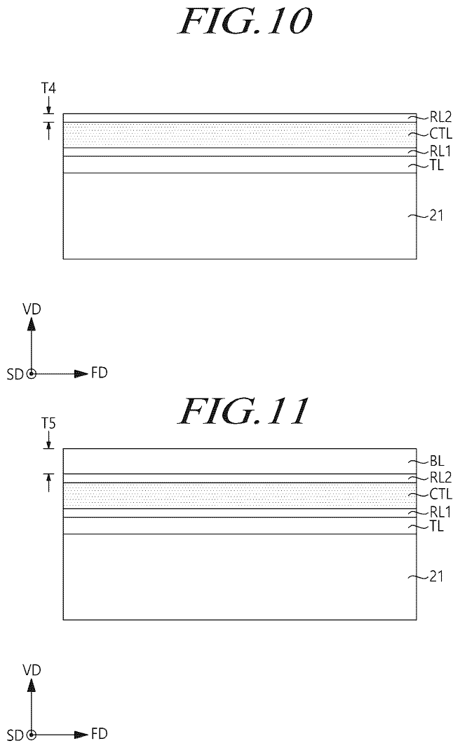

Referring to FIG. 10, a second resonant tunneling layer RL2 having a fourth thickness T4 may be formed on the charge trap layer CTL. The second resonant tunneling layer RL2 may include a material having a lower energy barrier than the charge trap layer CTL. The second resonant tunneling layer RL2 may include tantalum pentoxide (Ta2O5), gallium oxide (Ga2O3), gadolinium oxide (Gd2O3), lanthanum oxide (La2O3), hafnium oxide (HfO2), gallium nitride (GaN), or a combination thereof. In an embodiment, the second resonant tunneling layer RL2 may include a tantalum pentoxide (Ta2O5) layer.

Forming the second resonant tunneling layer RL2 may include a chemical vapor deposition (CVD) method, an atomic layer deposition (ALD) method, a cyclic deposition method, a sputtering method, a physical vapor deposition (PVD) method, or a combination thereof. The fourth thickness T4 of the second resonant tunneling layer RL2 may be smaller than the first thickness T1 of the tunnel layer TL. The second resonant tunneling layer RL2 may, for example, have a thickness of 0.5 nm to 3 nm.

Referring to FIG. 11, a blocking layer BL having a fifth thickness T5 may be formed on the second resonant tunneling layer RL2. The blocking layer BL may include a material having a higher energy barrier than the second resonant tunneling layer RL2 and the charge trap layer CTL. In an embodiment, the blocking layer BL may include an aluminum oxide (Al2O3) layer.

Forming the blocking layer BL may include a chemical vapor deposition (CVD) method, an atomic layer deposition (ALD) method, a cyclic deposition method, a sputtering method, a physical vapor deposition (PVD) method, or a combination thereof. The equivalent oxide thickness (EOT) of the blocking layer BL may be thicker than the equivalent oxide thickness (EOT) of the tunnel layer TL. The fifth thickness T5 of the blocking layer BL may be thicker than the first thickness T1 of the tunnel layer TL.

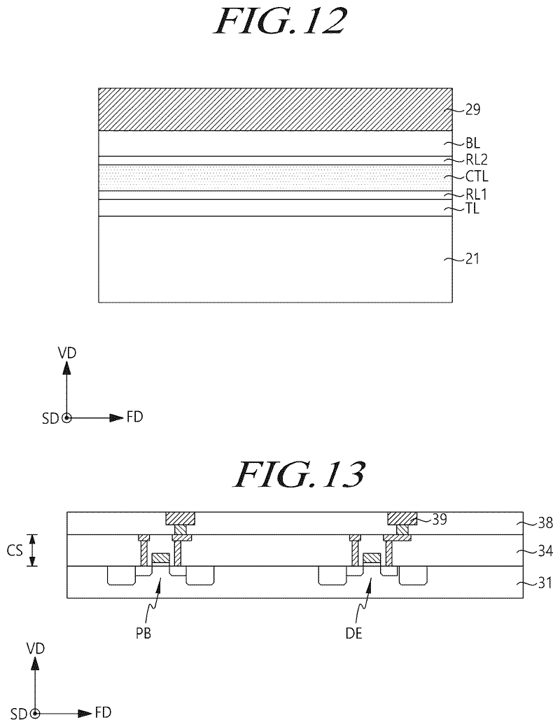

Referring to FIG. 12, a top electrode 29 may be formed on the blocking layer BL. The top electrode 29 may include a conductive material such as metal, metal nitride, metal oxide, metal silicide, polysilicon, conductive carbon or a combination thereof. The top electrode 29 may include W, WN, Ti, TiN, Ta, TaN, Ni, Co, Ru, Sn, Pt, Au, Ag, Cu, Al, or a combination thereof.

Referring to FIG. 1 again, by partially removing the top electrode 29, the blocking layer BL, the second resonant tunneling layer RL2, the charge trap layer CTL, the first resonant tunneling layer RL1 and the tunnel layer TL using a patterning process, the upper surface of the first substrate 21 may be exposed. The source and the drain regions 23 and 25 may be formed in the first substrate 21 using an ion implantation process. The channel pattern CP may be delimited in the first substrate 21 between the source and the drain regions 23 and 25. Each of the source and the drain regions 23 and 25 may include a semiconductor layer having N-type impurities.

In an embodiment, a heat treatment process for promoting crystallization of the tunnel layer TL, the first resonant tunneling layer RL1 and the second resonant tunneling layer RL2 may be additionally performed. The heat treatment process may be performed in an atmosphere of about 700° C. or less (e.g., 600° C. to 700° C.). The heat treatment process may be performed immediately after a process of forming each of the tunnel layers TL, the first resonant tunneling layer RL1 and the second resonant tunneling layer RL2 is completed. The heat treatment process may be performed once or several times between forming the second resonant tunneling layer RL2 and forming the source and the drain regions 23 and 25.

FIGS. 13 to 17 are cross-sectional views for describing a method of forming a semiconductor device based on an embodiment of the present disclosure.

Referring to FIG. 13, a circuit structure CS may be formed on a second substrate 31. A first insulating bonding layer 38 and a plurality of first bonding pads 39 may be formed on the circuit structure CS. The second substrate 31 may include a configuration similar to that described above with reference to FIG. 7. In an embodiment, the second substrate 31 may include a monocrystalline silicon wafer including P-type impurities. The circuit structure CS may be formed in and/or on the second substrate 31.

The circuit structure CS may include various types of active/passive elements such as transistors. The transistor may include a planar transistor, a recess channel transistor, a vertical transistor, a fin field effect transistor (finFET), a gate all around (GAA) transistor, a multi-bridge channel transistor, or a combination thereof. In an embodiment, the circuit structure CS may include a page buffer PB, a decoder DE and a circuit insulating layer 34.

The circuit insulating layer 34 may be formed on the second substrate 31 to cover the page buffer PB and the decoder DE. The first insulating bonding layer 38 may cover the circuit structure CS. The plurality of first bonding pads 39 may be formed in the first insulating bonding layer 38. The upper surfaces of the first insulating bonding layer 38 and the plurality of first bonding pads 39 may form substantially the same plane. Each of the plurality of first bonding pads 39 may be electrically connected to a corresponding at least one of the page buffer PB and the decoder DE.

Each of the circuit insulating layer 34 and the first insulating bonding layer 38 may include a single layer or a multilayer. Each of the circuit insulating layer 34 and the first insulating bonding layer 38 may include at least two selected from the group consisting of Si, O, N, C and B. Each of the circuit insulating layer 34 and the first insulating bonding layer 38 may include silicon oxide, silicon nitride, silicon oxynitride, silicon carbonitride (SiCN), silicon oxycarbonitride (SiOCN), low-k dielectric, high-k dielectric, or a combination thereof. In an embodiment, the first insulating bonding layer 38 may include silicon carbonitride (SiCN).

The plurality of first bonding pads 39 may include a single layer or a multilayer. The plurality of first bonding pads 39 may include metal, metal nitride, metal oxide, metal silicide, polysilicon, conductive carbon, or a combination thereof. The plurality of first bonding pads 39 may include Cu, Al, Ni, Co, Ru, W, WN, Ti, TiN, Ta, TaN, Sn, Pt, Au, Ag, or a combination thereof. In an embodiment, the plurality of first bonding pads 39 may include a Cu layer which is formed using an electroplating method.

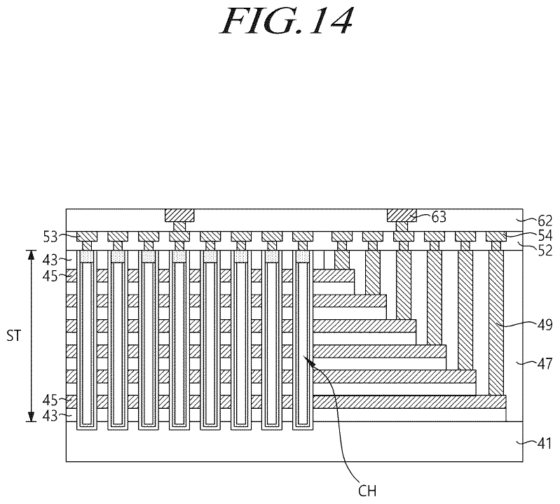

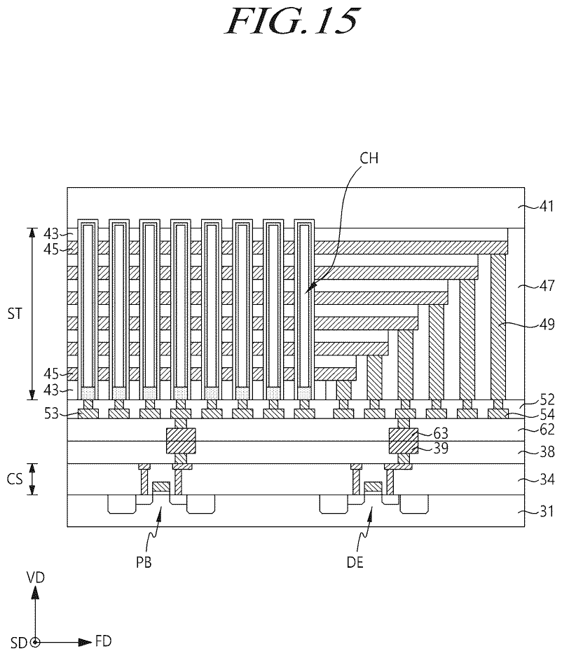

Referring to FIG. 14, a stack structure ST may be formed on a temporary substrate 41. The stack structure ST may include a plurality of molding layers 43 and a plurality of horizontal electrodes 45 which are alternately stacked. The plurality of molding layers 43 and the plurality of horizontal electrodes 45 may include a stairway structure. A buried insulating layer 47 may be formed on the plurality of molding layers 43 and the plurality of horizontal electrodes 45 which have the stairway structure.

A plurality of channel structures CH which extend into the temporary substrate 41 by passing through the stack structure ST may be formed. Similarly to the illustration of FIG. 4, each of the plurality of channel structures CH may include a core layer CO, a channel pattern CP, an information storage pattern DSL and a drain pad DP. The information storage pattern DSL may include a tunnel layer TL, a first resonant tunneling layer RL1, a charge trap layer CTL, a second resonant tunneling layer RL2 and a blocking layer BL.

In an embodiment, the core layer CO may include silicon oxide, silicon nitride, silicon oxynitride, polysilicon, or a combination thereof. The channel pattern CP may include a semiconductor material such as polysilicon. The drain pad DP may include a semiconductor material such as polysilicon. The information storage pattern DSL may include a configuration similar to that described above through FIGS. 1 to 12.

A plurality of contact plugs 49 may be formed to extend through the buried insulating layer 47 and connect to the plurality of horizontal electrodes 45. An interlayer insulating layer 52 may be formed on the stack structure ST, the plurality of channel structures CH, the buried insulating layer 47 and the plurality of contact plugs 49. A plurality of intermediate interconnections 53 and 54 may be formed in the interlayer insulating layer 52. The plurality of intermediate interconnections 53 and 54 may include a plurality of bit lines 53 and a plurality of word connecting interconnections 54.

Each of the plurality of bit lines 53 may be electrically connected to a corresponding at least one among the plurality of channel structures CH. Each of the plurality of word connecting interconnections 54 may be electrically connected to a corresponding at least one among the plurality of contact plugs 49. For the sake of convenience in description, the plurality of intermediate interconnections 53 and 54 are illustrated as being formed at the same layer, but may be formed at different layers.

A second insulating bonding layer 62 may be formed on the interlayer insulating layer 52. A plurality of second bonding pads 63 may be formed in the second insulating bonding layer 62. The upper (i.e., top) surfaces of the second insulating bonding layer 62 and the plurality of second bonding pads 63 may form substantially the same plane. Each of the plurality of second bonding pads 63 may be electrically connected to a corresponding one among the plurality of intermediate interconnections 53 and 54.

The temporary substrate 41 may include a material similar to the second substrate 31. Each of the plurality of molding layers 43, the buried insulating layer 47, the interlayer insulating layer 52 and the second insulating bonding layer 62 may be a single layer or a multilayer. Each of the plurality of molding layers 43, the buried insulating layer 47, the interlayer insulating layer 52 and the second insulating bonding layer 62 may include at least two selected from the group consisting of Si, O, N, C and B. Each of the plurality of molding layers 43, the buried insulating layer 47, the interlayer insulating layer 52 and the second insulating bonding layer 62 may include silicon oxide, silicon nitride, silicon oxynitride, silicon carbonitride (SiCN), silicon oxycarbonitride (SiOCN), low-k dielectric, high-k dielectric, or a combination thereof. The second insulating bonding layer 62 may include a material similar to that of the first insulating bonding layer 38. In an embodiment, the second insulating bonding layer 62 may include silicon carbonitride (SiCN).

Each of the plurality of horizontal electrodes 45, the plurality of contact plugs 49, the plurality of intermediate interconnections 53 and 54 and the plurality of second bonding pads 63 may include a single layer or a multilayer. Each of the plurality of horizontal electrodes 45, the plurality of contact plugs 49, the plurality of intermediate interconnections 53 and 54 and the plurality of second bonding pads 63 may include metal, metal nitride, metal oxide, metal silicide, polysilicon, conductive carbon, or a combination thereof. Each of the plurality of horizontal electrodes 45, the plurality of contact plugs 49, the plurality of intermediate interconnections 53 and 54 and the plurality of second bonding pads 63 may include Cu, Al, Ni, Co, Ru, W, WN, Ti, TiN, Ta, TaN, Sn, Pt, Au, Ag, or a combination thereof. The plurality of second bonding pads 63 may include a material similar to that of the plurality of first bonding pads 39. In an embodiment, the plurality of second bonding pads 63 may include a Cu layer which is formed using an electroplating method.

Referring to FIG. 15, the temporary substrate 41 with the stack structure ST and the second substrate 31 with the circuit structure CS may be combined. Specifically, the first insulating bonding layer 38 and the second insulating bonding layer 62 may be bonded to face each other, and the plurality of first bonding pads 39 and the plurality of second bonding pads 63 may be bonded to face each other.

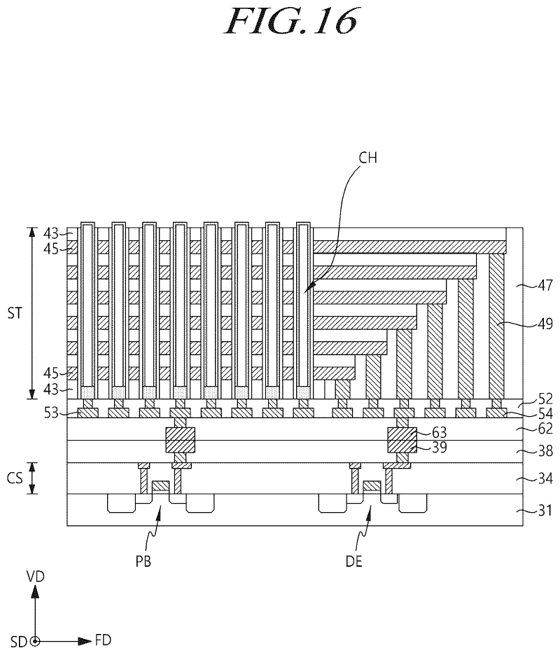

Referring to FIG. 16, the temporary substrate 41 is removed so that the stack structure ST and the plurality of channel structures CH are exposed. By partially removing the information storage pattern DSL, the channel pattern CP in each of the plurality of channel structures CH may be partially exposed.

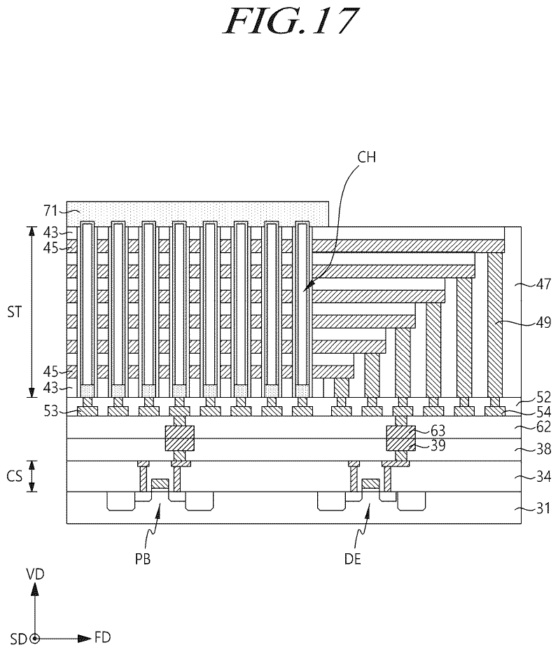

Referring to FIG. 17, a source line 71 covering the plurality of channel structures CH may be formed on the stack structure ST. The channel pattern CP may extend into the source line 71. The channel pattern CP may directly contact the source line 71. The source line 71 may include a semiconductor material such as polysilicon.

Referring to FIG. 6 again, the upper insulating layer 98 may be formed on the stack structure ST and the source line 71. The upper insulating layer 98 may include a single layer or a multilayer. The upper insulating layer 98 may include at least two selected from the group consisting of Si, O, N, C and B. The upper insulating layer 98 may include silicon oxide, silicon nitride, silicon oxynitride, silicon carbonitride (SiCN), silicon oxycarbonitride (SiOCN), low-k dielectric, high-k dielectric, or a combination thereof.

Although embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings. The spirit and scope of the present disclosure should be interpreted in connection with the appended claims and encompass all equivalents falling within the scope of the appended claims. Furthermore, the embodiments may be combined to form additional embodiments.

What is claimed is:

1. A semiconductor device comprising:
a channel pattern;
an electrode over the channel pattern; and
an information storage pattern between the channel pattern and the electrode,
wherein the information storage pattern comprises:
a tunnel layer adjacent to the channel pattern;
a blocking layer adjacent to the electrode;
a charge trap layer between the tunnel layer and the blocking layer;
a first resonant tunneling layer disposed between the tunnel layer and the charge trap layer; and
a second resonant tunneling layer disposed between the charge trap layer and the blocking layer.

2. The semiconductor device according to claim 1,
wherein the first resonant tunneling layer includes a material having a lower energy barrier than the tunnel layer, and
wherein the second resonant tunneling layer includes a material having a lower energy barrier than the charge trap layer.

3. The semiconductor device according to claim 1, wherein the second resonant tunneling layer includes a material having a lower energy barrier than the blocking layer.

4. The semiconductor device according to claim 1, wherein the first resonant tunneling layer includes a material having a lower energy barrier than the charge trap layer.

5. The semiconductor device according to claim 1,
wherein the first and the second resonant tunneling layers include tantalum pentoxide (Ta2O5), gallium oxide (Ga2O3), gadolinium oxide (Gd2O3), lanthanum oxide (La2O3), hafnium oxide (HfO2), gallium nitride (GaN), or a combination thereof.

6. The semiconductor device according to claim 1, wherein
the tunnel layer includes silicon oxide, silicon nitride, aluminum oxide, magnesium oxide or zirconium oxide,
the charge trap layer includes silicon nitride, and
the blocking layer includes aluminum oxide.

7. The semiconductor device according to claim 1, wherein the first resonant tunneling layer has a thickness smaller than that of the tunnel layer.

8. The semiconductor device according to claim 7, wherein
a thickness of the tunnel layer is 1 nm to 7 nm, and
a thickness of the first resonant tunneling layer is 0.5 nm to 3 nm.

9. The semiconductor device according to claim 1, wherein the second resonant tunneling layer has a thickness smaller than that of the tunnel layer.

10. The semiconductor device according to claim 9, wherein
a thickness of the tunnel layer is 1 nm to 7 nm, and
a thickness of the second resonant tunneling layer is 0.5 nm to 3 nm.

11. A semiconductor device comprising:
a channel pattern;
an electrode over the channel pattern; and
an information storage pattern between the channel pattern and the electrode,
the information storage pattern comprising:
a tunnel layer adjacent to the channel pattern;
a blocking layer adjacent to the electrode;
a charge trap layer between the tunnel layer and the blocking layer; and
at least one resonant tunneling layer disposed between the tunnel layer and the blocking layer, the at least one resonant tunneling layer including a material having a lower energy barrier than the tunnel layer and the blocking layer.

12. The semiconductor device according to claim 11, wherein the at least one resonant tunneling layer includes a material having a lower energy barrier than the charge trap layer.

13. The semiconductor device according to claim 11, wherein
the tunnel layer includes silicon oxide, silicon nitride, aluminum oxide, magnesium oxide or zirconium oxide, and
the at least one resonant tunneling layer includes tantalum pentoxide (Ta2O5), gallium oxide (Ga2O3), gadolinium oxide (Gd2O3), lanthanum oxide (La2O3), hafnium oxide (HfO2), gallium nitride (GaN), or a combination thereof.

14. The semiconductor device according to claim 11, wherein the at least one resonant tunneling layer has a thickness smaller than that of the tunnel layer.

15. The semiconductor device according to claim 14, wherein
a thickness of the tunnel layer is 1 nm to 7 nm, and
a thickness of the at least one resonant tunneling layer is 0.5 nm to 3 nm.

16. A semiconductor device comprising:
a stack structure including a plurality of molding layers and a plurality of horizontal electrodes which are alternately stacked;
a source line on the stack structure; and
a channel structure passing through the stack structure, and extending into the source line,
the channel structure comprising:
a channel pattern contacting the source line; and
an information storage pattern between the channel pattern and the stack structure,
the information storage pattern comprising:
a tunnel layer adjacent to the channel pattern;
a blocking layer adjacent to the stack structure;
a charge trap layer between the tunnel layer and the blocking layer; and
at least one resonant tunneling layer disposed between the tunnel layer and the blocking layer, and including a material having a lower energy barrier than the tunnel layer and the blocking layer.

17. The semiconductor device according to claim 16, wherein the at least one resonant tunneling layer includes a first resonant tunneling layer between the tunnel layer and the charge trap layer, the first resonant tunneling layer having a thickness smaller than that of the tunnel layer.

18. The semiconductor device according to claim 17, wherein the first resonant tunneling layer includes a material having a lower energy barrier than the charge trap layer.

19. The semiconductor device according to claim 16, wherein
the at least one resonant tunneling layer includes a second resonant tunneling layer which is disposed between the charge trap layer and the blocking layer and includes a material having a lower energy barrier than the charge trap layer, and
the second resonant tunneling layer has a thickness smaller than that of the tunnel layer.

20. The semiconductor device according to claim 16, wherein
the tunnel layer includes silicon oxide, silicon nitride, aluminum oxide, magnesium oxide or zirconium oxide, and
the at least one resonant tunneling layer includes tantalum pentoxide (Ta2O5), gallium oxide (Ga2O3), gadolinium oxide (Gd2O3), lanthanum oxide (La2O3), hafnium oxide (HfO2), gallium nitride (GaN), or a combination thereof.
